(19) United States
(12) Patent Application Publication
(10) Pub. No.: US 2025/0150014 A1
(43) Pub. Date: May 8, 2025

(54) INVERTER FOR AN ELECTRIC MACHINE

(71) Applicant: Robert Bosch GmbH, Stuttgart (DE)

(72) Inventors: Balazs Bence Harsanyi, Bietigheim-Bissingen (DE); Jan Homoth, Reutlingen (DE); Marco Graf, Tamm (DE); Matthias Heil, Hessigheim (DE); Michael Kott, Reutlingen (DE); Rudolf Ritter, Renningen (DE); Sebastian Strache, Wannweil (DE); Thoralf Rosahl, Eningen (DE)

(21) Appl. No.: 18/698,551

(22) PCT Filed: Oct. 6, 2022
(86) PCT No.: PCT/EP2022/077852

§ 371 Date: Jan. 22, 2025

(30) Foreign Application Priority Data
Oct. 11, 2021 (DE) 10 2021 211 423.7

(51) Int. Cl. H02P 27/08; G01R 15/14; G01R 15/20

(52) U.S. Cl. CPC H02P 27/08; G01R 15/148; G01R 15/20

(57) ABSTRACT

An inverter for an electric machine. The inverter has at least one semiconductor switch half-bridge. The inverter also has a current sensor, which is designed to detect a phase current generated by the at least one semiconductor switch half-bridge, depending on a magnetic field generated by the phase current. The inverter has a voltage source for supplying power to the current sensor. The voltage source is designed to supply the current sensor, in particular in a referenced manner, with an in particular constant supply voltage relative to the, in particular pulse-width-modulated, phase potential of the semiconductor switch half-bridge.

### FIELD

The present invention relates to an inverter for an electric machine. The inverter has at least one semiconductor switch half-bridge. The inverter also has a current sensor, which is designed to detect a phase current generated by the at least one semiconductor switch half-bridge, depending on a magnetic field generated by the phase current.

### BACKGROUND INFORMATION

European Patent No. EP 3 416 288 A1 describes a multi-stage gate driver for an inverter with a current sensor.

### SUMMARY

According to the present invention, the inverter of the type mentioned at the outset has a voltage source for supplying power to the current sensor. According to an example embodiment of the present invention, the voltage source is designed to supply the current sensor, in particular in a referenced manner, with an in particular constant supply voltage relative to the, in particular pulse-width-modulated, phase potential, in particular phase output potential, of the semiconductor switch half-bridge. Advantageously, occurring phase interference can thus be eliminated in the signal of the current sensor.

According to an example embodiment of the present invention, the inverter is preferably designed to supply the current sensor with a supply voltage relative to the phase potential in such a way that the supply voltage is modulated, in relation to a ground potential of the inverter, by means of the change in the phase potential. Advantageously, the supply voltage of the current sensor can thus be changed together with the phase potential.

The phase potential is preferably pulsed, in particular pulse-width-modulated. The inverter is preferably designed to generate a phase current of an electric machine for generating a rotating magnetic field. The current sensor, which draws the phase potential as a supply voltage, can thus generate a low-interference current output signal.

The semiconductor switch half-bridge preferably has a high-side semiconductor switch and a low-side semiconductor switch. The semiconductor switches, in particular the high-side semiconductor switch and the low-side semiconductor switch, are each preferably formed by a field-effect transistor. The field-effect transistor is preferably a MOSFET (MOS=metal oxide semiconductor), MISFET (MIS=metal-insulated semiconductor), an IGBT (insulated-gate bipolar transistor), or a HEMT (high-electron-mobility transistor). The semiconductor switches are each preferably formed as a housingless semiconductor switch, also referred to as a bare die.

In a preferred embodiment of the inverter of the present invention, the inverter has a gate driver for a high-side semiconductor switch of the semiconductor switch half-bridge and is designed to feed, in particular reference, the gate driver with the phase potential as a supply potential. Advantageously, the gate driver can thus be arranged together with the current sensor close to the phase output of the semiconductor switch half-bridge. Further advantageously, no additional complex supply lines need to be formed for supplying power to the gate driver.

In a preferred embodiment of the present invention, the inverter is designed to supply the current sensor with the high-side potential to be connected from a high-side semiconductor switch of the half-bridge as a further reference potential, in particular with a positive intermediate circuit potential. Advantageously, the gate driver can thus draw its reference potential from a busbar connected to the semiconductor switch half-bridge. Also advantageously, the power supply can be designed to have low interference, insofar as high-frequency interference caused in the output signal of the current sensor by switching pulses in the phase potential can be eliminated in this way.

The high-side potential to be connected from the high-side semiconductor switch is preferably a positive intermediate circuit potential, and thus the intermediate circuit potential applied to a drain terminal of the high-side semiconductor switch and to be connected through. The current sensor can thus receive the phase potential as the negative supply potential and receive a supply potential provided and derived from the intermediate circuit potential, in particular one that is constant in relation to the phase potential, as the positive supply potential.

In a preferred embodiment of the present invention, the inverter has a processing unit, which is connected to an input of the gate driver for a control signal and which is designed to transmit the control signal for actuating the half-bridge to the input of the gate driver. The inverter preferably has a low-voltage interface, which is designed to receive the control signal from the processing unit and to transmit the control signal to the gate driver, in particular in an electrically isolated manner.

Advantageously, the processing unit can thus be protected against voltage flashovers of a high voltage flashing over from the intermediate circuit to the processing unit.

According to example embodiment of the present invention, the interface is formed, for example, by an optocoupler, a capacitive or inductive coupler, or has an optocoupler, capacitive or inductive coupler. Advantageously, the low-voltage region can thus be electrically isolated from the high-voltage region in a cost-effective manner.

In a preferred embodiment of the present invention, the inverter has a phase busbar connected to the semiconductor switch half-bridge. The phase busbar is designed to conduct the phase current of the semiconductor switch half-bridge. In this embodiment, the current sensor is an in particular differential magnetic field sensor, which is arranged and formed in the region of the phase busbar to detect the phase current, depending on a magnetic field generated by a current flowing in the phase busbar. Advantageously, the phase current can thus be detected in a cost-effective manner and with little heat development, compared to a shunt resistor. Another advantage is that current detection and the actuation of the semiconductor switch half-bridge by the gate driver can thus be arranged in a compact and cost-effective manner on a substrate, in particular a printed circuit board, which is arranged in parallel with a ceramic substrate carrying the semiconductor switch half-bridge, in particular a DCB (DCB=direct copper bonded) circuit carrier or an AMB (AMB=active metal brazed) circuit carrier or IMS (IMS=insulated metal substrate) substrate. In this way, a compact and low-inductance arrangement can be formed.

In a preferred embodiment of the present invention, the voltage source for the current sensor is designed to generate a constant supply voltage for the current sensor. Advantageously, the current sensor can thus be reliably supplied with a supply voltage.

The current sensor is preferably a magnetic field sensor. Also preferably, the magnetic field sensor has at least one, two, or three Hall sensors, XMR sensors, and is designed to generate, depending on a magnetic field generated by a current, a current signal which represents the current, in particular an amperage of the current. For this purpose, the current sensor can have a Hall sensor or an XMR sensor. The magnetic field sensor can have a flux concentrator. In a preferred embodiment, the current sensor is a differentially detecting magnetic field sensor, which is designed to detect components of the magnetic field pointing in mutually different directions. The XMR sensor (XMR=X-magnetoresistive), is preferably an AMR sensor (AMR=anisotropic magnetoresistive), GMR sensor (GMR=giant magnetoresistive), or CMR sensor (CMR=colossal magnetoresistive), or TMR sensor (TMR =tunnel magnetoresistive).

In a preferred embodiment of the present invention, the voltage source for the current sensor is connected on the input side to an intermediate circuit of the inverter. Also preferably, the voltage source for the current sensor is connected on the input side to the phase potential, and to the intermediate circuit potential, in particular to the positive intermediate circuit potential.

Advantageously, the voltage supply for the current sensor can thus be supplied with voltage together with the gate driver.

In a preferred embodiment of the present invention, the gate driver, in particular a gate driver module, has the voltage supply source, in particular a voltage regulator, for the current sensor. The voltage regulator is preferably designed to compensate for supply voltage fluctuations of a supply voltage received on the input side, and to output, on the output side, an in particular constant DC voltage for supplying voltage to the current sensor.

In a preferred embodiment of the inverter of the present invention, the gate driver is arranged in the region of the current sensor, in particular in the spatial region of the current sensor, preferably in a common plane together with the current sensor. Advantageously, a short signal path between the current sensor and the gate driver, and thus also the voltage supply of the current sensor, can thus be formed. The current sensor is preferably arranged in the region of the phase busbar. The gate driver is preferably arranged in the region of the phase busbar.

In a preferred embodiment of the present invention, the inverter has a ceramic circuit carrier for the semiconductor switch half-bridge. The inverter also preferably has another circuit carrier arranged parallel thereto, wherein the current sensor and the gate driver, and more preferably also the processing unit, are each arranged on the additional circuit carrier and integrally connected to the additional circuit carrier. Advantageously, a low-inductance and low-noise arrangement of the inverter can thus be formed.

The present invention also relates to a method for detecting a phase current of a phase of an inverter for supplying current to an electric machine. According to an example embodiment of the present invention, in the method, the phase current is detected by a current sensor, depending on a magnetic field generated by the phase current, wherein the current sensor can draw supply voltage from a phase potential of the phase, in particular as a ground reference potential. Also preferably, the current sensor is supplied with an in particular positive supply voltage added to the phase potential. The supply voltage added to the phase potential is preferably a voltage generated, preferably converted, from the intermediate circuit voltage, in particular a positive intermediate circuit potential. The current sensor is thus advantageously referenced to the phase potential. The phase potential thus advantageously forms a ground terminal for the current sensor, and the derived, in particular down-converted, positive battery potential or intermediate circuit potential forms a positive supply terminal for the current sensor.

The present invention is explained in more detail below with reference to figures and further exemplary embodiments. Further advantageous embodiment variants result from a combination of the features disclosed herein.

### BRIEF DESCRIPTION OF THE DRAWINGS

FIG. 1 shows an exemplary embodiment of an inverter according to the present invention, in which a current sensor is referenced to a pulsed phase potential.

FIG. 2 is a sectional view of a commutation cell for the inverter shown in FIG. 1.

FIG. 3 is a diagram with signals that are generated by components of the inverter shown in FIG. 1.

### DETAILED DESCRIPTION OF EXAMPLE EMBODIMENTS

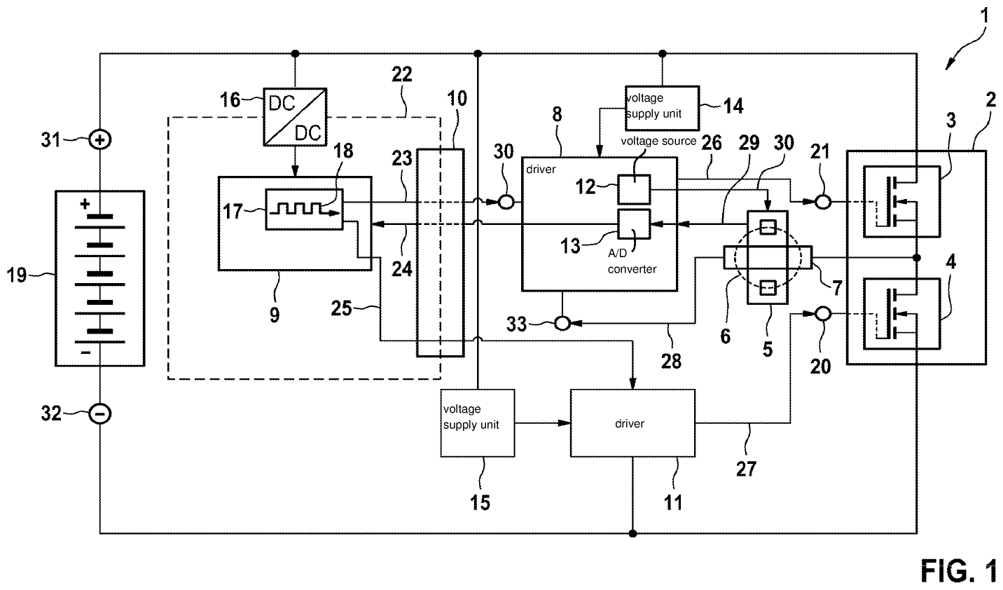

FIG. 1 schematically shows an exemplary embodiment of an inverter 1. The inverter 1 has at least one semiconductor switch half-bridge, of which one semiconductor switch half-bridge 2 is shown by way of example. For each phase, the inverter 1 can have at least one or only one semiconductor switch half-bridge.

The semiconductor switch half-bridge 2 has a high-side semiconductor switch 3 and a low-side semiconductor switch 4. The semiconductor switches 3 and 4 are formed, for example, by a field-effect transistor, in particular a housingless field-effect transistor, also referred to as a bare die.

The inverter 1 also has a current sensor 5, which is designed to detect a magnetic field 6 generated by a phase busbar 7, in particular a current flowing in the phase busbar 7, and to generate a current signal representing the phase current detected depending on the magnetic field 6, and to output it on the output side.

The inverter 1 also has a driver 8, which is designed to actuate the high-side semiconductor switch 3 for connecting through or blocking. In this exemplary embodiment, the driver 8 is a high-side gate driver, which is connected on the output side to a control terminal 21 of the semiconductor switch half-bridge 2 by means of a connecting line 26, for the high-side semiconductor switch 3.

In this exemplary embodiment, the driver 8 also has a voltage source 12, which is formed by a voltage regulator in this exemplary embodiment. The voltage source 12 is a component of the driver 8, which is formed, for example, by an integrated semiconductor component. The driver 8 also has an analog-to-digital converter, which is connected to the current sensor 5 on the input side by means of a connecting line 29, and can thus receive the current signal generated by the current sensor 5 and can convert it from analog to digital. The analog-to-digital converter 13 is connected on the output side to a processing unit 9 by means of a connecting line 24. In this exemplary embodiment, the processing unit 9 is part of the inverter 1 and is formed, for example, by a microcontroller, a microprocessor, or an ASIC (ASIC=application-specific integrated circuit).

The processing unit 9 is designed to generate a pulse-width-modulated control signal 18, hereinafter also referred to as a PWM signal, for actuating the semiconductor switch half-bridge 2, and for this purpose in this exemplary embodiment has a pulse width modulator 17, which is designed to generate the control signal 18.

The inverter 1 also has a voltage converter 16, which is designed to generate a supply voltage for the processing unit from the intermediate circuit voltage and to supply the processing unit 9 with the supply voltage, which is generated from the intermediate circuit voltage, in particular down-converted therefrom.

The inverter 1 also has a positive terminal 31 for a positive battery potential and a negative terminal 32 for an in particular negative battery reference potential, in particular ground potential. FIG. 1 also shows by way of example a battery 19, which is a vehicle battery for an electric vehicle, for example.

The inverter 1 also has an interface 10, which is designed to isolate low-voltage components of the inverter 1, in this exemplary embodiment the processing unit 9, from the intermediate circuit voltage, in particular the battery potential, received at the terminals 31 and 32, or additionally from other high-voltage signals. In this exemplary embodiment, the interface 10 has an optocoupler, which is designed to transmit signals generated by the processing unit 9, for example the PWM signal 18, in an electrically isolated manner to the driver 8. For this purpose, the processing unit 9 is connected by means of a connecting line 23 to the driver 8, and at least indirectly there to an input 30 for the control signal, wherein the connecting line 23 extends through the interface 10, and the processing unit 9 and the driver 8 are thus indirectly connected to one another. A low-voltage region 22, in which low-voltage components of the inverter are arranged, is denoted by dashes in FIG. 1.

The analog-to-digital converter 13 is connected in an electrically isolated manner to the processing unit 9 by means of a connecting line 24, which extends through the interface 10, so that the processing unit 9 can receive the current signal generated by the current sensor 5, in digital form.

The processing unit 9 is designed to generate, depending on the current signal received on the input side, the pulse width modulation signal 18 for actuating the semiconductor switch half-bridge 2 and thus for indirectly supplying current to an electric machine, and thus for generating a rotating magnetic field.

The processing unit 9, in particular the pulse width modulator 17, is connected on the output side to a driver 11 of the inverter 1 by means of a connecting line 25. In this exemplary embodiment, the driver 11 is designed as a low-side gate driver and is connected on the output side to a control terminal 20 of the low-side semiconductor switch 4 of the semiconductor switch half-bridge 2 by means of a connecting line 27.

The driver 11 is designed to generate, depending on the PWM signal received on the input side from the processing unit 9, a control signal for connecting through or blocking the low-side semiconductor switch 4 and to transmit it on the output side to the low-side semiconductor switch 4.

In this exemplary embodiment, the connecting line 25 extends through the interface 10 so that the low-side gate driver 11 is electrically isolated from the processing unit 9.

The inverter 1 also has a voltage supply unit 14 for supplying the driver 8 and a voltage supply unit 15 for supplying voltage to the driver 11. The voltage supply units 14 and 15 are each designed to supply the driver 8 and the driver 11, respectively, with a supply voltage and, for this purpose, are connected on the input side to the intermediate circuit. The voltage supply units 14 and 15 are formed, for example, by buck converters.

The driver 8 has a terminal 33 for a reference potential, in particular a ground potential, and is connected to the phase busbar 7 by means of a connecting line 28. The phase busbar 7 is connected to the semiconductor switch half-bridge 2 and can receive the in particular PWM-clocked phase potential from the semiconductor switch half-bridge 2.

The driver 8 thus has the phase potential, received from the phase busbar 7, as a reference potential. The driver 11, in particular the low-side gate driver, has the negative intermediate circuit potential, received at terminal 32, as a reference potential in this exemplary embodiment. By means of the inverter formed in this manner, a voltage change coupling into the current sensor or into the current signal path can be avoided, insofar as the voltage supply for the current sensor 5 is coupled to the phase potential.

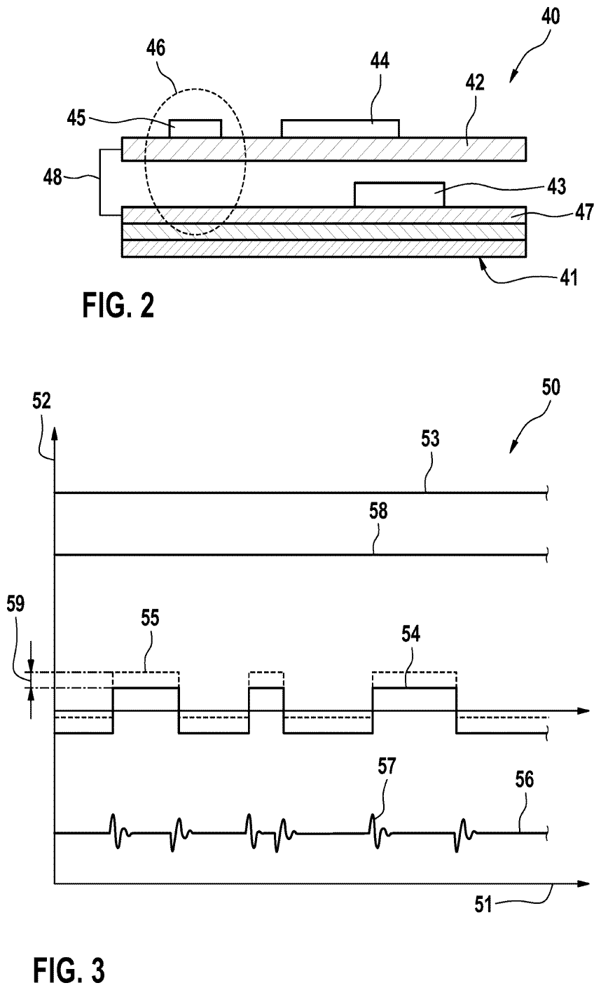

FIG. 2 is a schematic sectional view of an exemplary embodiment of a commutation cell 40. The commutation cell 40 can be a component of the inverter 1 shown in FIG. 1. The commutation cell 40 comprises a semiconductor switch half-bridge, of which a semiconductor switch 43 is shown by way of example. The semiconductor switch 43 is integrally connected, in particular soldered or sintered, to a substrate 41. The substrate 41 is, for example, a DCB substrate or an AMB substrate.

An electrically conductive layer 47 of the substrate 41 forms a phase busbar, which is coupled to a current sensor 45 by means of a magnetic field 46 generated by the phase current.

The current sensor 45 is connected to a circuit carrier 42 and can detect the magnetic field 46 and, depending on the detected magnetic field, can generate a current signal which represents the phase current flowing in the phase busbar 47.

The circuit carrier 42 is, for example, a printed circuit board or a ceramic circuit carrier, in particular a LTCC circuit carrier (LTCC=low-temperature co-fired ceramics). In this exemplary embodiment, the circuit carrier 42 is arranged parallel to the substrate 41.

The commutation cell 40 also comprises a driver 44, which is connected to the circuit carrier 42 and is designed to actuate the semiconductor switch half-bridge, and thus also the semiconductor switch 43 for switching through or blocking.

Both the driver 44 and the current sensor 45 are each designed to receive a reference potential, in particular a ground potential, from the phase busbar 47 and are electrically connected to the phase busbar 47 for this purpose, in this exemplary embodiment by means of a connecting line 48. The connecting line 48 is formed, for example, by a flexible printed circuit board, in particular a conductor track of a flexible printed circuit board.

FIG. 3 is a diagram 50, which has an abscissa 51, wherein the abscissa 51 represents a time axis. The diagram 50 also has an ordinate 52, which forms an amplitude axis.

The diagram 50 shows a curve 54, which represents a PWM signal 54 (PWM=pulse width modulation) generated in particular by the pulse width modulator 17 shown in FIG. 1.

The diagram 50 also shows a curve 55, which is shifted by a voltage difference 59 relative to the curve 54 and represents the aforementioned reference potential for supplying the current sensor 5 and, in the exemplary embodiment shown in FIG. 1, for supplying the driver 8.

It can be seen that the reference potential 55 is clocked together with the control pulses of the PWM signal 54.

The diagram 50 also shows a curve 56, which represents a current signal, generated by a current sensor which is not coupled to the phase potential. The curve 56 has interfering signals, which are generated in each case by the switching on and off processes at the beginning and at the end of a PWM pulse, and which can be interspersed in the current signal path. An interference pulse 57 is denoted by way of example.

The diagram 50 also shows a curve 58, which represents a current signal generated by the current sensor 5 in FIG. 1. The current signal of the current sensor 5, represented by the curve 58, is free of interference signals, insofar as the current sensor 5 is coupled to the phase potential of the semiconductor switch half-bridge 2, and thus to the phase output signal of the semiconductor switch half-bridge.

The diagram 50 also shows a curve 53, which represents a course of a supply voltage for the current sensor 5, generated and provided by the voltage source 12 of the inverter 1.

The current sensor 5 can thus be supplied with a constant supply voltage, which is referenced to the phase potential, in particular the phase output potential of the semiconductor switch half-bridge 2.

1-10. (canceled)

11. An inverter for an electric machine, comprising:
at least one semiconductor switch half-bridge;
a current sensor configured to detect a phase current generated by the at least one semiconductor switch half-bridge, depending on a magnetic field generated by the phase current; and
a voltage source configured to supply power to the current sensor, the voltage source being configured to supply the current sensor with a constant supply voltage relative to a pulse-width-modulated, phase potential of the semiconductor switch half-bridge.

12. The inverter according to claim 11, further comprising:
a gate driver for a high-side semiconductor switch of the semiconductor switch half-bridge, and the inverter is configured to feed the gate driver with the phase potential as a supply potential.

13. The inverter according to claim 11, wherein the inverter is configured to supply the current sensor with the high-side potential to be connected from a high-side semiconductor switch of the semiconductor switch half-bridge, as a further reference potential including a positive intermediate circuit potential.

14. The inverter according to claim 12, further comprising:
a processing unit connected to an input of the gate driver for a control signal and configured to transmit the control signal for actuating the semiconductor switch half-bridge to the input of the gate driver; and
a low-voltage interface configured to receive the control signal from the processing unit and to transmit the control signal in an electrically isolated manner to the gate driver.

15. The inverter according to claim 11, further comprising:
a phase busbar connected to the semiconductor switch half-bridge, the phase busbar being configured to carry the phase current of the semiconductor switch half-bridge, and wherein the current sensor is a differential magnetic field sensor, which is arranged in a region of the phase busbar.

16. The inverter according to claim 11, wherein the voltage source for the current sensor is configured to generate the constant supply voltage for the current sensor.

17. The inverter according to claim 11, wherein the voltage source is connected on an input side to an intermediate circuit of the inverter.

18. The inverter according to claim 11, wherein the gate driver is arranged in a region of the current sensor.

19. The inverter according to claim 18, further comprising:
a ceramic circuit carrier for the semiconductor switch half-bridge; and
an additional circuit carrier arranged in parallel with the ceramic circuit carrier;
wherein the current sensor and the gate driver are arranged on the additional circuit carrier and are integrally connected to the additional circuit carrier.

20. A method for detecting a phase current of a phase of an inverter for supplying current to an electric machine, the method comprising:
detecting a phase current, using a current sensor, depending on a magnetic field generated by the phase current, wherein the current sensor is supplied from a supply voltage added to a phase potential of a phase.
